(19) United States
(12) Patent Application Publication
(10) Pub. No.: US 2026/0020296 A1
(43) Pub. Date: Jan. 15, 2026

(54) SUPERJUNCTION DEVICE AND METHOD FOR PRODUCING A SUPERJUNCTION REGION

(71) Applicant: Infineon Technologies AG, Neubiberg (DE)

(72) Inventors: Andreas VÖRCKEL, Finkenstein (AT); Caspar LEENDERTZ, München (DE)

(21) Appl. No.: 19/256,646

(22) Filed: Jul. 1, 2025

(30) Foreign Application Priority Data
Jul. 9, 2024 (DE) 102024206451.3

(51) Int. Cl. H10D 62/10; H10D 30/66; H10D 62/00

(52) U.S. Cl. CPC H10D 62/111; H10D 30/668; H10D 62/054

(57) ABSTRACT

A superjunction device and a method for producing a superjunction device are disclosed. The superjunction device includes a semiconductor body including an inner region and an edge region laterally surrounding the inner region; a superjunction region comprising first regions of an effective first doping type and second regions of an effective second doping type arranged alternatingly in a first lateral direction of the semiconductor body. The first regions, in the inner region, have a first width and are spaced apart from each other at a first distance, in the edge region, have a second width and are spaced apart from each other at a second distance, and, in the inner region and the edge region, are elongated in a second lateral direction different from the first lateral direction. The second width is smaller than the first width and the second distance is smaller than the first distance.

### RELATED APPLICATION

This application claims priority to German Patent Application No. 102024206451.3, filed on Jul. 9, 2024, entitled “SUPERJUNCTION DEVICE AND METHOD FOR PRODUCING A SUPERJUNCTION REGION”, which is incorporated by reference herein in its entirety.

### TECHNICAL FIELD

The present disclosure relates to a superjunction device including s superjunction region, and a method for producing a superjunction region of a superjunction device.

### BACKGROUND

A vertical superjunction device, such as a superjunction transistor device, includes a superjunction region with a plurality of first regions of a first doping type and a plurality of second regions of a second doping type complementary to the first doping type. The superjunction region is arranged in an inner region and an edge region of a semiconductor body of the superjunction device. The edge region surrounds the inner region in lateral directions of the semiconductor body and is devoid of active device regions, such as source and body regions in a transistor device. The first and second regions may be arranged alternatingly in a lateral direction of the semiconductor body.

The first regions are connected to a first terminal and the second regions are connected to a second terminal different from the first terminal of the superjunction device. In a transistor device, for example, the first and second terminals are drain and the source terminals. The superjunction device is in an off-state (blocking state) when PN junctions between neighboring first and second regions are reverse biased, so that space charge regions (depletion regions) expand in the neighboring first and second regions of the superjunction region. The expansion of depletion regions in the first and second regions is associated with an electric field. A voltage blocking capability is reached and an Avalanche breakdown may occur when the voltage applied between the first and second terminals is such that a magnitude of the electric field reaches a critical value.

In many cases it is desirable to design a superjunction transistor device such that a voltage blocking capability in the inner region is lower than in the edge region so that an Avalanche breakdown, if there is one, occurs in the inner region, which has a greater area (and volume) in comparison to the edge region.

There is therefore a need for providing a superjunction transistor device such that a voltage blocking capability in the edge region is higher than in the inner region.

### SUMMARY

One example relates to a superjunction device. The superjunction device includes a semi-conductor body having an inner region and an edge region laterally surrounding the inner region, a superjunction region including first regions of an effective first doping type and second regions of an effective second doping type arranged alternatingly in a first lateral direction of the semiconductor body. The first regions, in the inner region, have a first width and are spaced apart from each other at a first distance, in the first edge region section, have a second width and are spaced apart from each other at a second distance, and, in the inner region and the edge region, are elongated in a second lateral direction different from the first lateral direction. The second width is smaller than the first width and the second distance is smaller than the first distance.

Another example relates to a method for forming a superjunction region of a superjunction device. The superjunction device includes a semiconductor body including an inner region and an edge region laterally surrounding the inner region; a superjunction region including first regions of an effective first doping type and second regions of an effective second doping type arranged alternatingly in a first lateral direction of the semiconductor body, wherein the first regions, in the inner region, have a first width and are spaced apart from each other at a first distance, in the first edge region section, have a second width and are spaced apart from each other at a second distance, in the inner region and the edge region, are elongated in a second lateral direction different from the first lateral direction, and wherein the second width is smaller than the first width and the second distance is smaller than the first distance. Forming the superjunction region includes implanting dopant atoms of the first doping type into a semiconductor layer having a doping concentration of the second doping type, and an annealing process.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A-1C schematically illustrate a horizontal cross-sectional view of a superjunction region arranged in a semiconductor body of a superjunction device, wherein FIG. 1A illustrates an overall view of the superjunction region, FIG. 1B illustrates one example of a detailed view of the superjunction region in an inner region of the semiconductor body, and FIG. 1C illustrates one example of a detailed view of the superjunction region in the edge region;

FIGS. 2A-2B illustrate one example of the superjunction region illustrated in FIGS. 1A-1C in detail;

FIGS. 3-5 illustrate different examples of transitions of the superjunction region between the inner region and the edge region;

FIG. 6 illustrates a horizontal cross-sectional view of a superjunction region according to another example;

FIG. 7 schematically illustrates a vertical cross-sectional view of a superjunction transistor device that includes a superjunction region;

FIGS. 8-9 illustrate different examples of transistor cells of a superjunction transistor device of the type illustrated in FIG. 7;

FIG. 10 illustrates a modification of the superjunction transistor device according to FIG. 7;

FIGS. 11-12 illustrate vertical cross-sectional views of edge regions of superjunction devices according to different examples;

FIGS. 13A-13C illustrate one example of a method for forming first regions of a first doping type and second regions of a second doping type of a superjunction region;

FIG. 14 illustrates another example of a method for forming first and second regions of a superjunction region; and

FIGS. 15A-15C illustrate a modification of the method according to FIGS. 13A-13C.

### DETAILED DESCRIPTION

The examples described herein provide for a superjunction device and for a method for producing a superjunction region of a superjunction device.

Although specific examples have been illustrated and described herein, it will be appreciated by those of ordinary skill in the art that a variety of alternate and/or equivalent implementations may be substituted for the specific examples shown and described without departing from the scope of the disclosed subject matter. This application is intended to cover any adaptations or variations of the specific examples discussed herein. Therefore, it is intended that the disclosed subject matter be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the disclosed subject matter and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the disclosed subject matter, as well as specific examples thereof, are intended to encompass equivalents thereof.

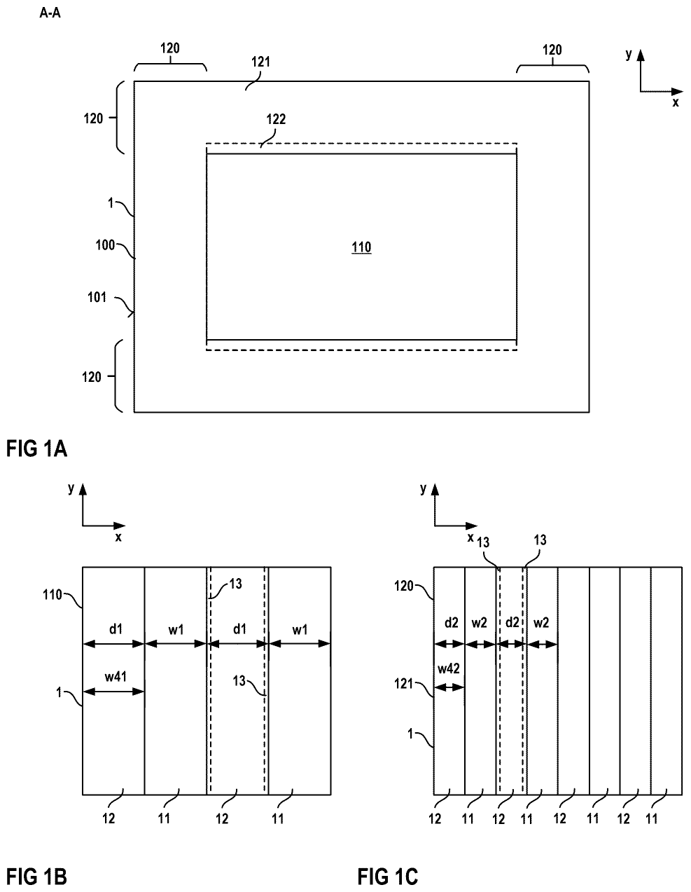

FIGS. 1A-1C schematically illustrate a horizontal cross-sectional view of a superjunction region 1 arranged in a semiconductor body 100 of a superjunction device. The semiconductor body 100 includes a monocrystalline semiconductor material. According to one example, the monocrystalline semiconductor material is silicon carbide (SiC). According to another example, the monocrystalline semiconductor material is silicon (Si).

FIG. 1A illustrates an overall review of the superjunction region 1. Referring to FIG. 1, the semiconductor body 100 includes an inner region 110 and an edge region 120 that laterally surrounds the inner region 110. That is, the edge region 120 surrounds the inner region 110 in lateral directions of the semiconductor body 100. FIG. 1B illustrates one example of a detailed view of one portion of the superjunction region 1 arranged in the inner region 110, and FIG. 1C illustrates one example of a detailed view of one portion of the superjunction region 1 arranged in the edge region 120.

Referring to FIGS. 1B-1C, the superjunction region 1 includes first regions 11 of a first doping type and second regions 12 of a second doping type that are arranged alternatingly in a first lateral direction x of the semiconductor body 100. As used herein, “first doping type” denotes an effective first doping type. That is, in a doped region of the first doping type dopant atoms of the first doping type prevail so that the doped region effectively has a first doping type. Equivalently, “second doping type” denotes an effective second doping type. That is, in a doped region of the second doping type dopant atoms of the second doping type prevail so that the doped region effectively has a second doping type. Dopant atoms of the first doping type are P-type dopant atoms, and dopant atoms of the second doping type are N-type dopant atoms, for example. According to another example, dopant atoms of the first doping type are N-type dopant atoms, and dopant atoms of the second doping type are P-type dopant atoms.

Referring to FIGS. 1B-1C, the first and second regions 11, 12, in the inner region 110 and the edge region 120, are elongated in a second lateral direction y. According to one example, the second lateral direction y is at least approximately perpendicular to the first lateral direction x in which the first and second regions 11, 12 are arranged alternatingly. According to one example, “elongated” includes that the dimension of the first and second regions 11, 12 in the second lateral direction y is much larger than the dimension in the first lateral direction x. In the following, the dimension of the first and second regions 11, 12 in the first lateral direction x is referred to as width. The dimension in the second lateral direction y may be referred to as length.

In the inner region 110, the first regions 11 have a first width w1 and are spaced apart from each other at a first distance d1. In the edge region 120, the first regions 11 have a second width w2 and are spaced apart from each other at a second distance d2. The first width w1 is larger than the second width w2, and the first the distance d1 is larger than the second distance d2.

According to one example, the first width w1 is selected from a range of between 1.2 times and 3 times the second width w2, and the first the distance d1 is selected from a range of between 1.2 times and 5 times the second distance d2. According to one example, in absolute values, the first width w1 is selected from a range of between 0.5 micrometers (μm) and 2 micrometers.

According to one example, neighboring first and second regions 11, 12 essentially adjoin one another. In this example, the first distance d1 at least approximately equals a width w41 of the second regions 12 in the inner region 110,

$$d 1 \approx w 41 \qquad ( 1 )$$

and the second distance d2 at least approximately equals a width w42 of the second regions in the edge region 120,

$$d 2 \approx w 42 . \qquad ( 2 )$$

Furthermore, in this example, at a PN junction between the first and second regions 11, 12, there is an abrupt change from the doping concentration of the first doping type of a respective first region 11 to the doping concentration of the second doping type of a respective neighboring second region 12.

According to another example illustrated in dashed lines in FIGS. 1B-1C, the superjunction region 1 includes a third region 13 arranged between each pair of neighboring first and second regions 11, 12. The third region 13 has a lower (effective) doping concentration than each of the first and second regions 11, 12. According to one example, a doping concentration of the third region 13 is less than 10% of the doping concentration of each of the first and second regions 11, 12, so that the doping concentration of the third region 13 is at least one order of magnitude lower than the doping concentration of each of the first and second regions 11, 12.

According to one example, the doping concentration of the first and second regions 11, 12 is selected from a range of between 5E16 cm⁻³ and 5E18 cm⁻³ , and the doping concentration of the third region is selected from a range of between 1E15 cm⁻³ and 1E16 cm⁻³ . According to one example, the first and second regions 11, 12 at least approximately have the same doping concentration. That is, for example, the doping concentration of the first regions 11 deviates less than 10%, less than 5%, or even less than 1% from the doping concentration of the second regions 12.

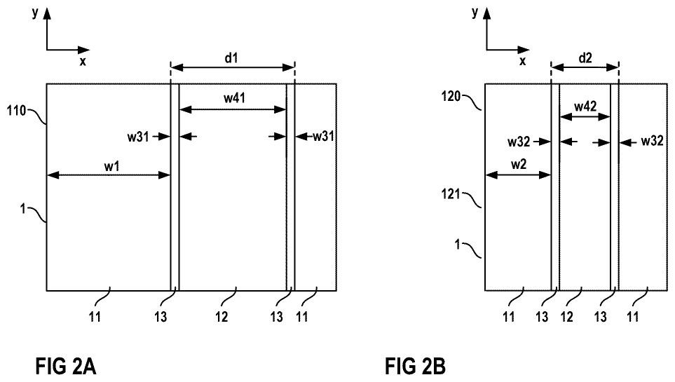

FIGS. 2A-2B illustrate the example in which third regions 13 are arranged between the first and second regions 11, 12 in greater detail. Referring to FIGS. 2A-2B, the third regions 13 have a width w31 in the inner region 110, and a width w32 in the edge region. According to one example, the width w31 of the third region 13 in the inner region 110 at least approximately equals the width w32 in the edge region 120.

The second regions 12 have a width w41 in the inner region 110 and a width w42 in the edge region 120, wherein the width w41 in the inner region is larger than a width w42 in the edge region 120. As can be seen from FIG. 2A, the first distance d1 between neighboring first regions 11 in the inner region 110 is essentially given by the width w41 of the second region 12 arranged between the two neighboring first regions 11 plus the widths w31 of the two third regions 13 arranged between the second region 12 and the neighboring first regions 11,

$$d 1 \approx w 41 + 2 \cdot w 31. \qquad ( 3 )$$

As can be seen from FIG. 2B, the first distance d2 between neighboring first regions 11 in the edge region 120 is essentially given by the width w42 of the second region 12 arranged between the two neighboring first regions 11 plus the widths w32 of the two third regions 13 arranged between the second region 12 and the neighboring first regions 11,

$$d 2 \approx w 42 + 2 \cdot w 32. \qquad ( 4 )$$

According to one example, the first width w1 of the first regions 11, which is the width in the inner region 110, at least approximately equals the width w41 of the second regions 12 in the inner region 110,

$$w 1 \approx w 41 \qquad ( 5 )$$

and the second width w2, which is the width in the edge region 120, at least approximately equals the width w42 of the second regions 12 in the edge region 120,

$$w 2 \approx w 42 . \qquad ( 6 )$$

Furthermore, the effective first type doping concentration of the first regions 11 may at least approximately equal the effective second type doping concentration of the second regions 12 and, in the optional case that third regions 13 are arranged between the first and second regions 11, 12, the third region 13 are at least approximately intrinsic. In this example, lateral dopant doses of the first regions 11 in the inner region 110 at least approximately equal the dopant doses of the second regions 12 in the inner region 110, and lateral dopant doses of the first regions 11 in the edge region 120 at least approximately equal the dopant doses of the second regions 12 in the edge region 120. The “lateral dopant dose” is the integral of the doping concentration in the first lateral direction x, which is the direction in which the first and second regions 11, 12 are arranged alternatingly.

By implementing the first regions 11 such that the widths w2 of the first regions 11 in the edge region 120 are smaller than widths w1 of the first regions 11 in the inner region 110 and by implementing the second regions 12 such that the widths w42 of the second regions 12 in the edge region 120 are smaller than widths w42 of the second regions 12 in the inner region 110, the lateral dopant doses of the first and second regions 11, 12 in the edge region 120 are lower than the lateral dopant doses of the first and second regions 11, 12 in the inner region 110. This results in an increased Avalanche robustness of the superjunction device.

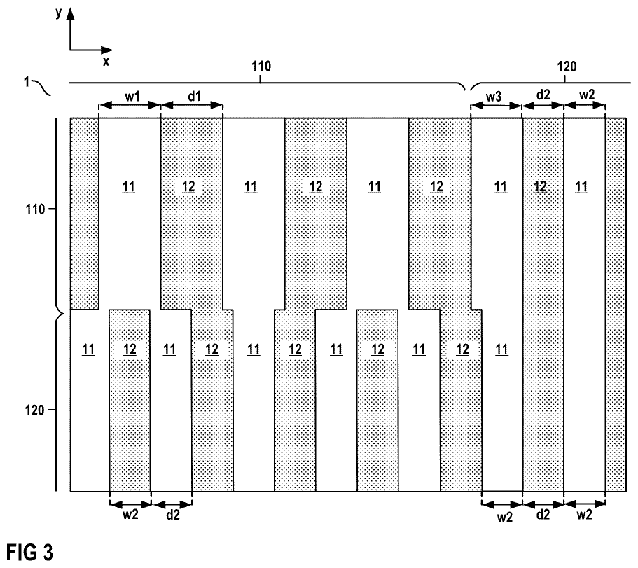

FIGS. 1B and 2A each illustrate a portion of the superjunction region 1 arranged in the inner region 110 of the semiconductor body 100, and FIGS. 1C and 2B each illustrate a portion of the superjunction region 1 arranged in the edge region 120 of the semiconductor body. In particular in the second lateral direction y, various kinds of transitions from the first width w1 in the inner region 110 to the second width w2 in the edge region 120 and from the first distance d1 in inner region 110 to the second distance d2 in the edge region 120 are possible. Some examples are explained with reference to FIGS. 3-5 in the following.

Each of FIGS. 3-5 illustrates a horizontal cross-sectional view of one portion of the superjunction region 1 that is partially arranged in the inner region 110 and the edge region 120. Everything explained herein before with regard to the first and second widths w1, w2 and the first and second distances d1, d2 applies to each of the examples illustrated in FIGS. 3-5. Furthermore, in each of these examples, the first and second regions 11, 12 may adjoin each other or may be separated from each other by respective third regions 13, although the latter are not illustrated in FIGS. 3-5.

According to one example illustrated in FIG. 3, in the second lateral direction y, there is an abrupt transition between the first regions 11 having the first width w1 and the first distance d1 in the inner region 110 and the second width w2 and the second distance d1 in the edge region 120. According to one example, the first and second regions 11, 12 are implemented such that, in the second lateral direction y, one first region 11 arranged in the inner region 110 adjoins at least one first region 11 arranged in the edge region 120 and one second region 12 arranged in the inner region 110 adjoins at least one second region 12 arranged in the edge region 120.

Referring to the above, first regions 11 arranged in the inner region 110 may have at least approximately the same lateral first type dopant dose as first regions 11 arranged in the outer region 120, and second regions 12 arranged in the inner region 110 may have at least approximately the same lateral second type dopant dose as second regions 12 arranged in the edge region 120. In this way, in the first lateral direction x, first type dopant charges and second type dopant charges are balanced both in the inner region 110 and the edge region 120.

In the first lateral direction x, at a transition between the inner region 110 and the edge region 120, one first region 11 may have a third width w3 that is different from the first and second widths w1, w2. This is in order to maintain the charge balance where the width of the first regions 11 changes from the first width w1 in the inner region 110 to the second width w2 in the edge region 120 and the distance changes from the first distance d1 in the inner region 110 to the second distance d2 in the edge region 120. According to one example, the third width w3 is given by the average of the first and second widths w1, w2,

$$w 3 = \frac{w 1 + w 2}{2} . \qquad ( 7 )$$

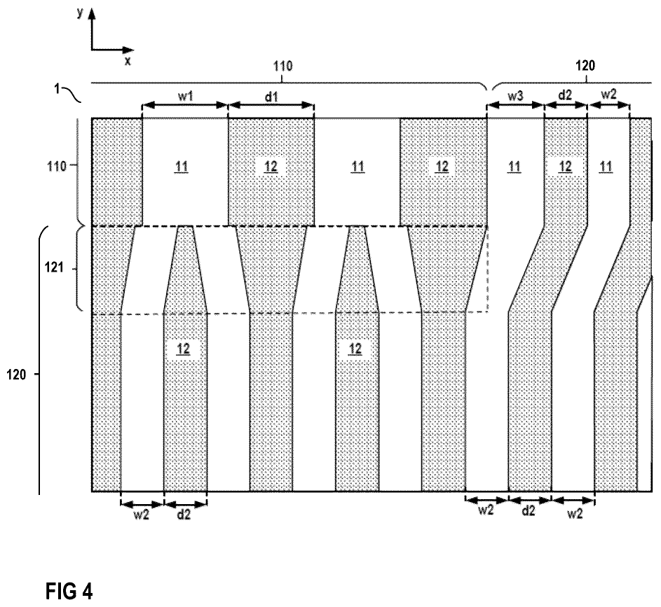

According to another example illustrated in FIG. 4, each of the first regions 11 arranged in the inner region 110, in the second lateral direction y, merges into two first regions 11 arranged in the edge region 120. In this example, the first width w1 is at least approximately two times the second width w2, w1≈2·w2. Referring to FIG. 4, there is a transition region 121 that adjoins the inner region 110 in the second lateral direction y. In the transition region 121, there are first pairs of neighboring first regions 11 and second pairs of neighboring first regions 11. In the transition region 121, the distance between the first regions 11 of the first pairs is smaller than the second distance d2 close to the inner region 110 and, in the first lateral direction y, increases to the second distance d2. Furthermore, the distance between the first regions 11 of the second pairs is larger than the second distance d2 close to the inner region 110 and, in the first lateral direction y, decreases to the second distance d2. In the transition region 121, the first regions 11 at least approximately have the second width w2. By having first pairs of neighboring first regions 11 the distance of which decreases in the first lateral direction y and by having second pairs of neighboring first regions 11 the distance of which increases in the first lateral direction y, a charge balance in the transition region 121 is maintained.

In the first lateral direction x, at a transition between the inner region 110 and the edge region 120, one first region 11 may have a third width w3 that is different from the first and second widths w1, w2. This is in order to maintain the charge balance. In the same way as explained with reference to FIGS. 3, the third width w3 is given by the average of the first and second widths w1, w2, for example.

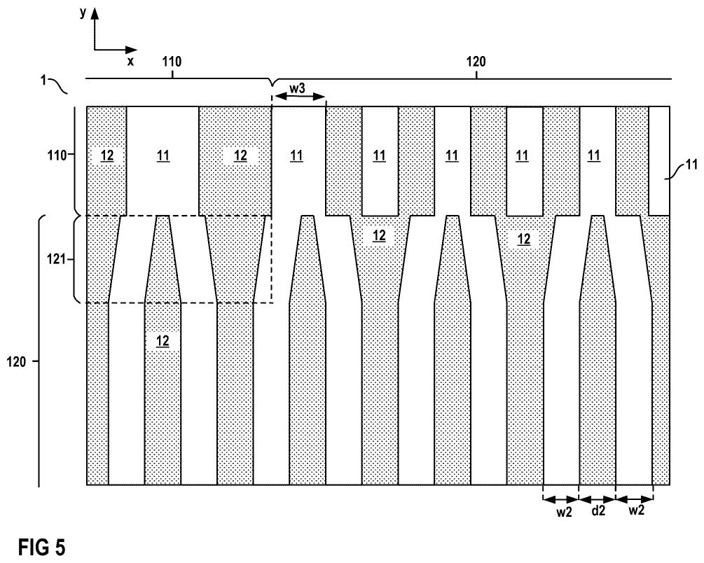

FIG. 5 illustrates a modification of the superjunction region 1 illustrated in FIG. 4. The superjunction region 1 illustrated in FIG. 5 is different from the superjunction region 1 illustrated in FIG. 4 in that, in a region adjacent to the inner region 110 in the second lateral direction, the superjunction region 1 includes first regions 11 of a first type and first regions 11 of a second type that are arranged alternatingly in the first lateral direction x. The first regions 11 of the first type, in the second lateral direction y, terminate at a lateral position at which the inner region 110 terminates in the second lateral direction y. The first regions 11 of the second type, in the second lateral direction y, merge into two first regions 11 that have the second width w2.

Furthermore, in the first lateral direction x, at a transition between the inner region 110 and the edge region 120, one first region 11 may have a third width w3 that is different from the first and second widths w1, w2 in order to maintain the charge balance. In the same way as explained with reference to FIGS. 3, the third width w3 is given by the average of the first and second widths w1, w2, for example.

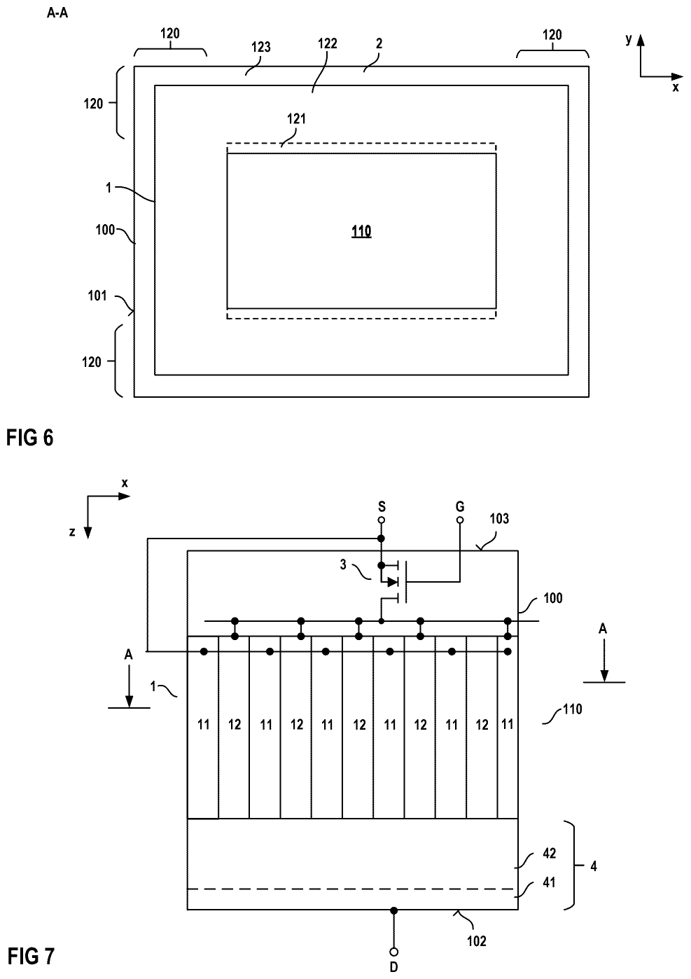

Referring to FIG. 1A, the semiconductor body 100 has an edge surface 101, which is a surface that terminates the semiconductor body 100 in lateral directions. As illustrated in FIG. 1A, the superjunction region 1 may extend to the edge surface 101 in each lateral direction. According to another example illustrated in FIG. 6, the superjunction region 1 may terminate spaced apart from the edge surface 101. In this example, the edge region 120 includes a first edge region section 122 that surrounds the inner region 110 in lateral directions and in which a portion of the superjunction region 1 is arranged. Furthermore, the edge region 120 includes a second edge region section 123 that is arranged between the first edge region section 122 and the edge surface 101 and that is devoid of the superjunction region 1. According to one example, the second edge region section 123 has an essentially homogeneous doping concentration of either the first doping type or the second doping type. According to one example, the second edge region section 123 has a is lower doping concentration than the first and second regions 11, 12 of the superjunction region 1. According to another example, the doping concentration of the second edge region section 123 at least approximately equals the doping concentration of the first and second regions 11, 12.

The superjunction region 1 explained herein before can be implemented in various kinds of superjunction devices, such as superjunction transistor devices or superjunction diodes. One example of a superjunction transistor device that includes a superjunction region 1 of the type explained herein before is illustrated in FIG. 7 and explained in the following.

FIG. 7 schematically illustrates a vertical cross sectional view of one portion of a superjunction transistor device. More specifically, FIG. 7 illustrates one portion of a semiconductor body 100 of the transistor device in a vertical section plane that is defined by the first lateral direction x in which the first and second regions 11, 12 are arranged alternatingly, and a vertical direction z perpendicular to the first lateral direction x. Furthermore, FIG. 7 illustrates one portion of the inner region 110 of the semiconductor body 100.

Referring to FIG. 7, the first regions 11 are connected to a first load path node S of the transistor device, and the second regions 12 are connected to a second load path node D of the transistor device. The first load path node S is a source node and the second load path node D is a drain node, for example. A connection between the first regions 11 and the first load path node S is only schematically illustrated in FIG. 7. Examples of how these connections can be implemented are explained with reference to examples herein further below.

According to one example, the second regions 12 are connected to the first load path node D via a further semiconductor region 41 of the second doping type, which is referred to as a drain region 41 in the following. The drain region 41 may adjoin the second regions 12. This, however, is not shown in FIG. 7. Optionally, as shown in FIG. 7, a buffer region 42 of the second doping type is arranged between the drain region 41 and the second regions 12. According to one example, a doping concentration of the buffer region 42 is lower than a doping concentration of the drain region 41. According to one example, the doping concentration of the buffer region 42 is lower than the doping concentration of the drain region 41 and may be less than 50%, less than 20% or even less than 5% of the doping concentration of the drain region 41. According to one example, the doping concentration of the drain region 41 is selected from between 1E18 cm⁻³ and 1E19 cm⁻³ , and the doping concentration of the buffer region 42 is selected from between 2E15 cm⁻³ and 3E18 cm⁻³ .

According to one example, the buffer region 42 is at least approximately homogeneously doped. According to another example, the buffer region 42 includes two or more differently doped layers arranged between the drain region 41 and the superjunction region 1.

According to one example, the buffer region 42 is essentially homogeneously doped. According to another example, the doping concentration of the buffer region 42 varies in the lateral direction z such that the buffer region 42 includes at least two differently doped regions of the first doping type.

The drain region 41 and the optional buffer region 42 may be part of a contiguous semiconductor layer 4 of the first doping type, wherein the semiconductor layer 4 is arranged between the superjunction region 1 and a first surface 102 of the semiconductor body 100. The semiconductor layer 4 may include a semiconductor substrate that forms the drain region 41 and an epitaxial layer formed on the substrate and forming the buffer region 42.

Referring to FIG. 1, the superjunction device further includes a head structure 3 connected between the source node S and the second regions 12. The head structure 3 may at least partially be integrated in the semiconductor body 100. That is, the head structure 3 may at least partially be arranged between the superjunction region 1 and a second surface 103 opposite the first surface 102 of the semiconductor body 100. According to one example, the head structure 3 includes a plurality of transistor cells. Examples of the transistor cells are explained herein further below. In the example illustrated in FIG. 7, the transistor cells are represented by the circuit symbol of a transistor. Just for the purpose of illustration, the circuit symbol illustrated in FIG. 7 represents an N-type enhancement MOSFET (Metal Oxide Semiconductor Field-Effect Transistor). The transistor device, however, is not restricted to be implemented as an N-type enhancement MOSFET. It is also possible to implement the transistor device as an N-type depletion MOSFET, a P-type enhancement or depletion MOSFET, or a JFET (Junction Field-Effect Transistor).

Referring to FIG. 7, the transistor device further includes a control node G, which may also be referred to as gate node G. In a conventional way, a voltage applied between the gate node G and the source node S controls a conducting channel between the source node S and the second regions 12 of the superjunction region 1 and, therefore controls whether the transistor device is in an on-state or an off-state.

The transistor device according to FIG. 7, the second regions 12 may also be referred to as a drift regions and the first regions 11 may also be referred to as compensation regions.

Referring to the above, the transistor device can be operated in an on-state or an off-state. The transistor device is in the on-state when there is a conducting channel in the head structure 3 between the source node S and the second regions 12. In this operating state, a current can flow via the second regions 12 of the superjunction region 1 when a suitable load path voltage (drain-source voltage) is applied between the drain and source nodes D, S. The transistor device is in the off-state when the conducting channel is interrupted and a voltage is applied between the drain and source nodes S, D that reverse biases the PN junctions between the first and second regions 11, 12 of the superjunction region 1. In the off-state of the superjunction device, space charge regions (depletion regions) expand in the first regions 11 and the second regions 12, so that the first regions 11 and the second regions 12 may become depleted of charge carriers as the load path voltage increases and absorb the drain source voltage applied between the drain node D and the source node S.

The superjunction device may be implemented as an N-type device or as a P-type device. In an N-type device, the first doping type is a P-type and the second doping type, which is the doping type of the second regions 12 and the drain region 41, is an N-type. In a P-type device, the first doping type is an N-type and the second doping type is a P-type.

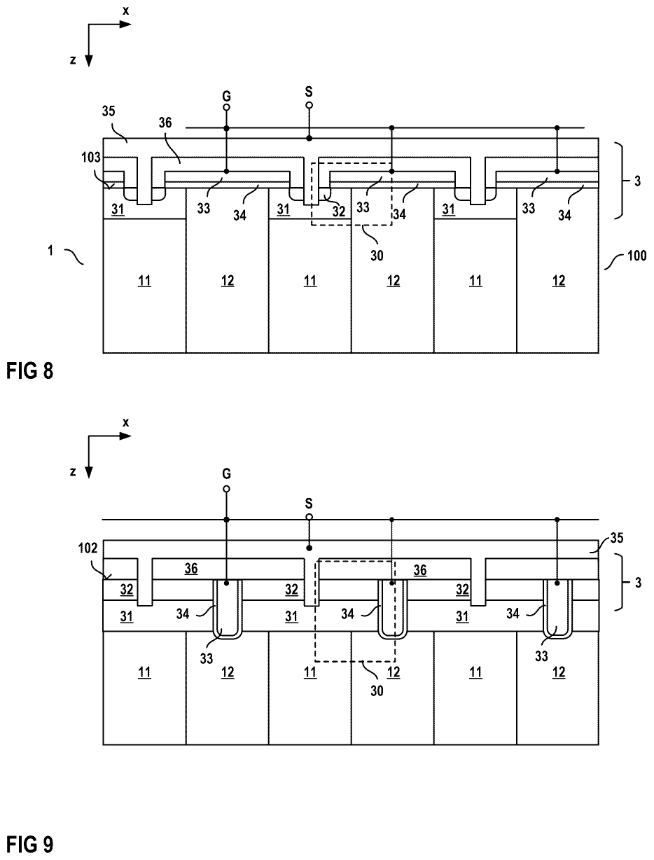

FIG. 8 shows one example of the head structure 3 of the superjunction transistor device in greater detail. More specifically, FIG. 8 shows examples of the transistor cells 30 included in the head structure 3. Besides the head structure 3, only a portion of the superjunction region 1 adjoining the head structure 3 is shown in FIG. 8.

Referring to FIG. 9, each transistor cell 30 includes a body region 31 of the first doping type, a source region 32 of the second doping type, a gate electrode 33, and a gate dielectric 34. The gate dielectric 34 dielectrically insulates that gate electrode 33 from the body region 31. The body region 31 of each transistor cell 30 separates the respective source region 32 from at least one of the plurality of second regions (drift regions) 12. The source region 32 and the body region 31 of each of the plurality of transistor cells 30 is electrically connected to the source node S of the transistor device. “Electrically connected” in this context means ohmically connected. That is, there is no rectifying junction between the source node S and the source region 32 and the body region 31. According to one example, the source and body regions 32, 31 are connected to a source metallization 35 that is electrically insulated from the gate electrodes 33 by an insulating layer 36. The source metallization 35 forms the source node S or is connected to the source node S of the transistor device. The gate electrode 33 of each transistor cell 30 is electrically connected to the gate node G of the transistor device.

Referring to the above, the body region 31 of each transistor cell adjoins at least one second region 12. As the body region 31 is of the first doping type and the second region 12 is of the second doping type there is a PN junction between the body region 31 of each control transistor cell 30 and the at least one second region 11. These PN junctions form a PN diode, which is sometimes referred to as body diode of the transistor device.

The gate electrodes 33 of the transistor cells 30 are configured to control conducting channels in the body regions 31 along the gate dielectrics 34 between the source regions 32 and the first regions 11 dependent on a gate-source voltage between the gate node G and the source node S. The transistor device is in the on-state when the gate-source voltage is such that there are conducting channels along the gate dielectrics 34. The transistor device is in the blocking state when the gate-source voltage is such that the conducting channels are interrupted and a polarity of the drain-source voltage is such that the PN junctions between the second regions 12 and the body regions 31 are reverse biased. This is commonly known, so that no further explanation is required in this regard.

In the example shown in FIG. 8, the gate electrode 33 of each transistor cell 30 is a planar electrode arranged on top of the second surface 103 of the semiconductor body 100 and dielectrically insulated from the semiconductor body 100 by the respective gate dielectric 34.

FIG. 9 shows a head structure 3 with transistor cells 30 according to another example. The transistor cells 30 shown in FIG. 9 are different from the transistor cells 30 shown in FIG. 8 in that the gate electrode 33 of each transistor cell 30 is a trench electrode. That is, each gate electrode 33 is arranged in a respective trench that extends from the second surface 103 into the semiconductor body 100. Like in the example shown in FIG. 8, a gate dielectric 34 dielectrically insulates the gate electrode 33 from the respective body region 31. The body region 31 and the source region 32 of each transistor cell 30 are electrically connected to the source node S. Further, the body region 31 adjoins at least one second region 12 and forms a PN junction with the respective second region 12.

In the examples shown in FIGS. 8 and 9 the transistor cells each include one gate electrode 33, wherein the gate electrode 33 of each transistor cell 30 is configured to control a conducting channel between the source region 32 of the respective transistor cell 30 and one second region 12, so that each transistor cell is associated with one second region 12. Furthermore, as shown in FIGS. 8 and 9, the body region 31 of each transistor cell 30 adjoins at least one first region 11, so that the first regions 11 are electrically connected to the source node S via the body regions 31 of the transistor cells 30.

Just for the purpose of illustration, in the examples shown in FIGS. 8 and 9, the body region 31 of each transistor cell 30 adjoins one first region 11 so that each transistor cell 30 is associated with one first region 11. Furthermore, in the examples, shown in FIGS. 8 and 9, the source regions 32 of two (or more) neighboring transistor cells are formed by one doped region of the second doping type, the body regions 31 of two (or more) neighboring transistor cells 30 are formed by one doped region of the first doping type, and the gate electrodes 33 of two (or more) transistor cells 30 are formed by one electrode. The gate electrodes 33 may include doped polysilicon, a metal, or the like.

The source regions 32 and the body regions 31 may be produced by implanting dopant atoms via the first surface 103 into the semiconductor body 100. According to one example, the source regions 32 are produced such that their doping concentration is higher than 8E18 cm⁻³ and the body regions 31 are produced such that their doping concentration is between 1E17 cm⁻³ and 1E18 cm⁻³ .

In addition to the body regions 31 and the second regions 12, the transistor device may include shielding regions (not shown) of the second doping type. A doping concentration of these shielding regions may be higher than the doping concentration of the body regions 31. The shielding regions adjoin the body regions 31 and/or the first regions 11 and extend into the second regions 12. The shielding regions and the first regions 11 form JFET (Junction Field Effect Transistor) like structures that protect the gate dielectrics 34 against high electric fields as the drain-source voltage in the blocking state increases. This is commonly known so that no further explanation is required in this regard.

Associating one transistor cell of the plurality of transistor cells with one first region 11 and one second region 12, as illustrated in FIGS. 8 and 9, is only an example. The implementation and the arrangement of the transistor cells of the head structure 3 are widely independent of the specific implementation of the superjunction region 1 with the first regions 11 and the second regions 12.

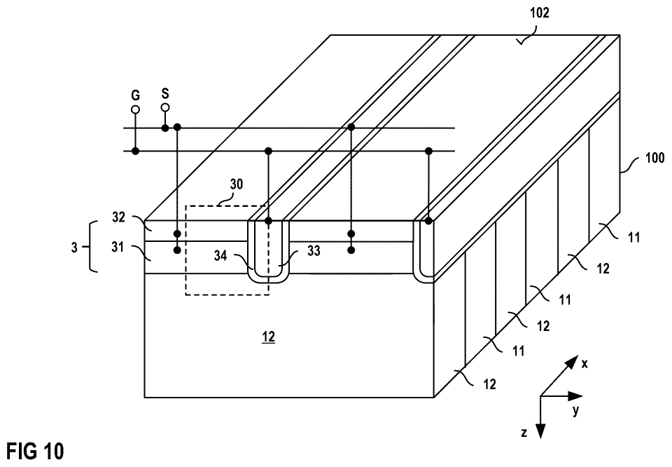

One example illustrating that the implementation and arrangement of the head structure 3 with the transistor cells 30 is widely independent of the implementation of the superjunction region 1 with the first and second regions 11, 12 is shown in FIG. 10.

In the example illustrated in FIG. 10, the first regions 11 and the second regions 12 are elongated in the second lateral direction y of the semiconductor body 100, while the source regions 32, the body regions 31, and the gate electrodes 33 of the individual control transistor cells 30 of the head structure 3 are elongated in the first lateral direction x perpendicular to the second lateral direction y. This is different from the examples illustrated in FIGS. 8 and 9, in which the source regions 32 and the body regions 31 are elongated in the second lateral direction y. In the example illustrated in FIG. 10, one transistor cell 30 adjoins a plurality of first regions 11 and a plurality of second regions 12.

In the examples illustrated in FIGS. 7 to 10, the drain region 41, the optional buffer region 42, and the source regions 32 are doped regions of the second doping type, so that the doping type of these regions is complementary to the doping type of the first regions 11 and the same as the doping type of the second regions 12. This, however, is only an example.

According to another example, the drain region 41, the optional buffer region 42, and the source regions 32 are doped regions of the first doping type, so that the doping type of these regions is the same as the doping type of the first regions 11 and complementary to the doping type of the second regions 12. In this example, the body regions 31 have a doping type complementary to the doping type of the first regions 11. Furthermore, in this example, the first regions 11 are drift regions of the transistor device and the second regions 12 are compensation regions of the transistor device. The first doping type is an N-type, for example.

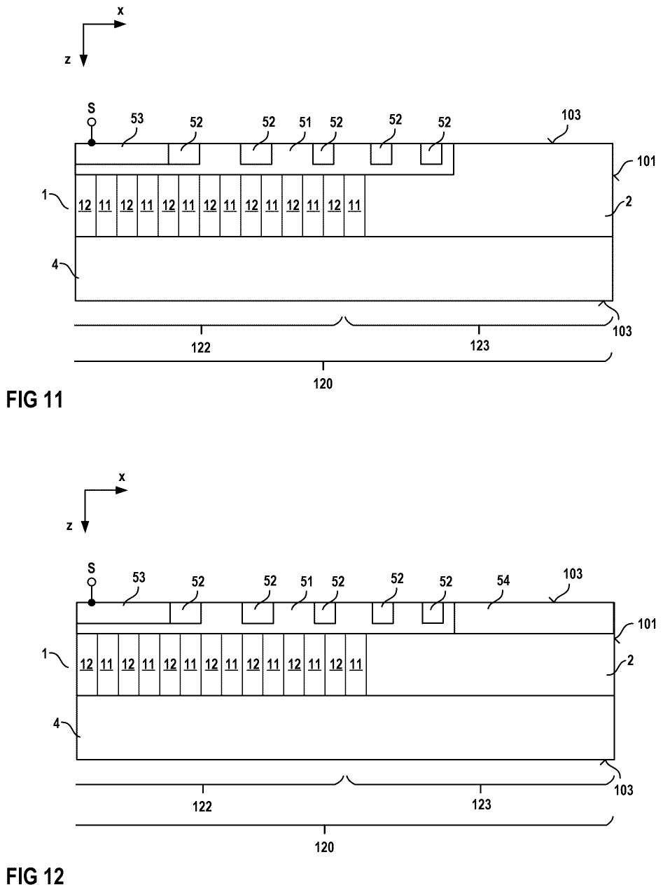

FIG. 11 illustrates a vertical cross-sectional view of one example of the edge region 120 in a superjunction transistor device in which the superjunction region 1 is implemented in accordance with the example illustrated in FIG. 6, so that the superjunction region 1 is spaced apart from the edge surface 101. As FIG. 11 only illustrates the edge region 120, transistor cells 30, which are only arranged in the inner region 110, are not shown in FIG. 6. The transistor cells can be implemented in accordance with any of the examples explained herein before.

Referring to FIG. 11, the first regions 11 of the first doping type arranged in the edge region 120 are electrically coupled to a first doped region 51 of the first doping type which is electrically connected to the source node S through a second doped region 53 of the first doping type. The second doped region 53 is a contact region and has a higher doping concentration than the first doped region 51. The connection between the second doped region and the source node S is only schematically illustrated in FIG. 11. This electrical connection may be implemented in a conventional way. Referring to FIG. 11, the first doped region 51, in the vertical direction z, is arranged between the superjunction region 1 and the second surface 103 of the semiconductor body 100.

Referring to FIG. 11, the edge region 120 may further include field rings 52 of the second doping type that are embedded in the first doped region 51. The field rings 52 are spaced apart from each other in lateral directions and, in a ring-shaped fashion, surround the inner region 110.

Referring to FIG. 11, the second edge region 123, in regions that lateral adjoin the superjunction region 1, may include a fourth region 2 two of the second doping type. The fourth region 2 laterally surrounds the superjunction region 1 and may have the same doping concentration as the second regions 12. A lateral extension of the fourth region 2, however, is much larger than the widths of the second regions 12 both in the inner region 110 and the edge region 120.

FIG. 12 shows a modification of the edge region 120 according to FIG. 11. In the example illustrated in FIG. 12, the edge region 120 further includes a doped region 54 of the second doping type that is arranged between the doped region 51 of the first doping type and the edge surface 101 and that is arranged between the first surface 103 and the fourth region 2. According to one example, a doping concentration of the doped region 54 of the second doping type is lower than the doping concentration of the fourth region 2.

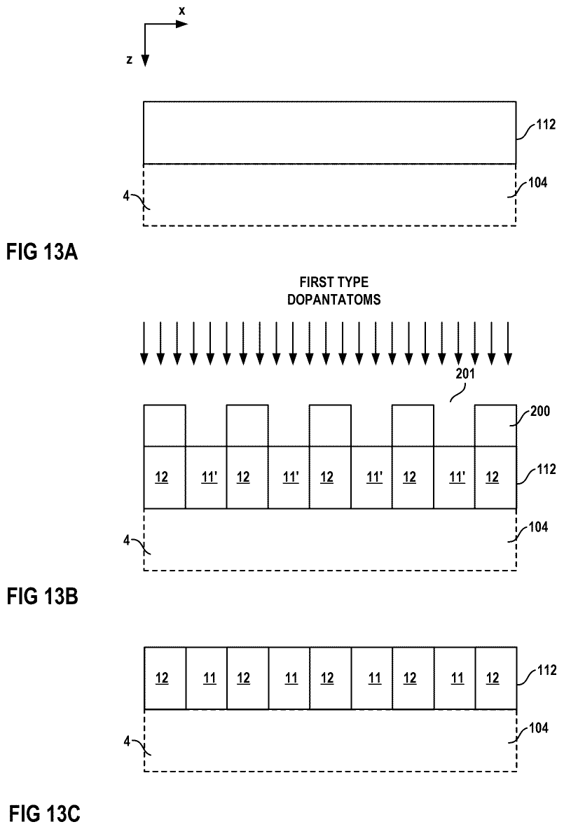

FIGS. 13A-13C illustrate one example of a method for forming the first and second regions 11, 12 of the superjunction region 1. Each of FIGS. 13A-13B illustrates a vertical cross-sectional view of one portion of the semiconductor body 100 during the manufacturing process.

Referring to FIG. 13A, the method is based on providing a semiconductor layer 112 that has the second doping type and a doping concentration that equals the desired doping concentration of the second regions 12 of the superjunction region 1. According to one example, the semiconductor layer 112 is an epitaxial layer that is formed on the semiconductor layer 104 forming the drain region and the optional buffer region of a transistor device explained herein before.

Referring to FIG. 13B, the method includes forming an implantation mask 200 on top of a surface of the semiconductor layer 112. The implantation mask 200 includes openings 201 which define the position and the size of the first regions 11 of the finished superjunction region 1. Referring to FIG. 13B, the method includes implanting first type dopant atoms via the openings 201 of the implantation mask 200 into the semiconductor layer 112 in order to form implanted regions 11′. The implanted regions 11′ include second type dopant atoms resulting from the basic doping of the epitaxial layer 112 and first type dopant atoms resulting from the implantation process. The implantation process may include two or more implantation processes in which first type dopant atoms are implanted at different implantation energies in order to implant first type dopant atoms into different depths of the epitaxial layer 112.

According to one example, the first type dopant atoms are P-type dopant atoms. In this example, the implanted dopant atoms are aluminum (Al) atoms or boron (B) atoms, for example. According to another example, the first type dopant atoms are N-type dopant atoms. In this example, the implanted dopant atoms are phosphorous (P) or nitrogen (N) atoms, for example. As explained above, the semiconductor material of the semiconductor body is SiC, for example.

According to one example, the basic doping of the epitaxial layer 112 is generated by in-situ doping during the epitaxial growth process in which the epitaxial layer 112 is grown. According to another example, the basic doping of the epitaxial layer 112 is generated by a blanket implantation process in which dopant atoms of the second doping type are implanted into the epitaxial layer 112. This implantation process may take place before or after implanting the first type dopant atoms that form the implanted regions 11′. The same annealing process may be used to activate the implanted first and second type dopant atoms.

Referring to FIG. 13C, the method further includes removing the implantation mask 200 and an annealing process. In the annealing process the implanted first type dopant atoms are activated and the first regions 11 having the effective doping concentration of the first doping type are formed. An overall implantation dose in the implantation process explained with reference to FIG. 13B is such that the first regions 11, in consideration of the basic doping of the epitaxial layer, have the desired effective doping concentration explained herein above. As the first and second regions 11, 12 are formed based on the same epitaxial layer 112 having a basic doping concentration of the second doping type, the first and second regions 11, 12 have the same net doping concentration of dopant atoms of the second doping type. In the first regions 11, the net doping of the second doping type is overcompensated by the implantation of the first type dopant atoms.

In the method illustrated in FIGS. 13A-13C, the first type dopant atoms are implanted into one epitaxial layer 112 to form the superjunction region 1. This, however, is only an example.

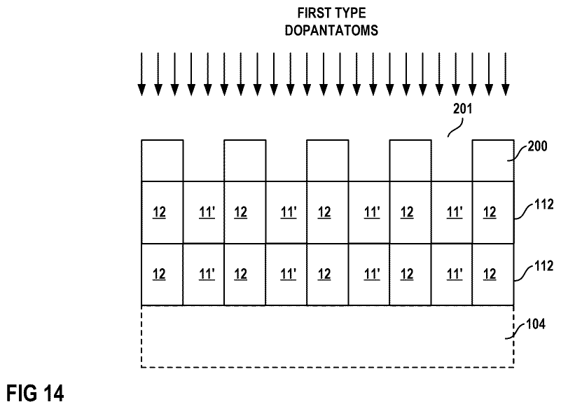

According to another example illustrated in FIG. 14, two or more epitaxial layers 112 of the second doping type are formed one above the other and dopant atoms of the first doping type are implanted into each of the epitaxial layers 112 using a respective implantation mask 200. FIG. 14 shows two epitaxial layers 112 formed one above the other. This, however, is only an example. An arbitrary number of two or more epitaxial layers 112 can be formed one above the other. According to one example, the first type dopant atoms implanted into the individual epitaxial layers 112 are activated by a common annealing process after the first type dopant atoms have been implanted into the last (uppermost) one of the two or more epitaxial layers 112.

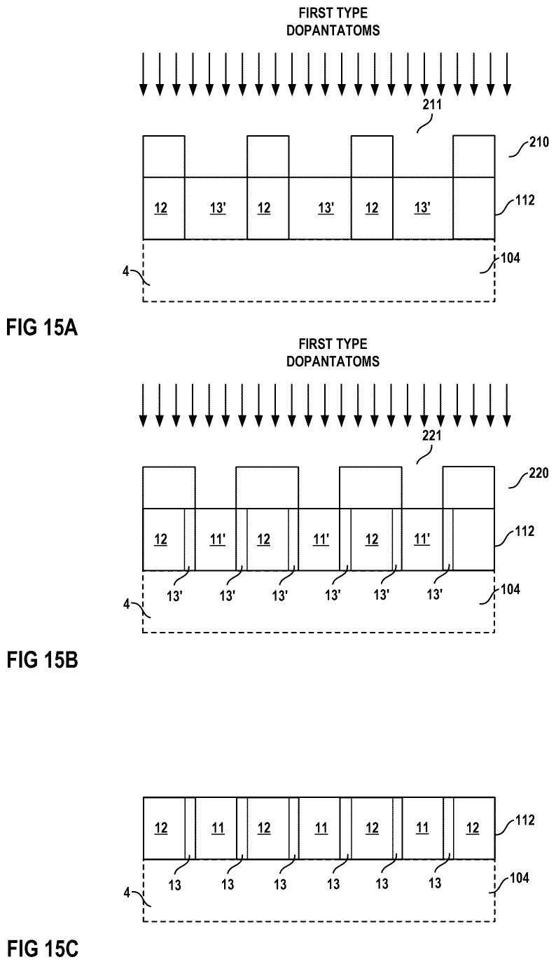

In the methods according to FIGS. 13A-13C and 14, the first regions 11 directly adjoin the second regions 12. As explained above, the superjunction region 1 can be implemented such that a third region 13 having a lower doping concentration than each of the first and second regions 11, 12 is arranged between each pair with a first region 11 and a neighboring second region 12. One example of a method for forming a superjunction region 1 of this type is illustrated in FIGS. 15A-15C.

Referring to FIG. 15A, this method includes forming a first implantation mask 210 on top of the epitaxial layer 112 and a first implantation process. The first implantation process includes implanting first type dopant atoms via openings 211 in the first implantation mask 210 into the epitaxial layer 112 to form first implanted regions 13′. Regions of the epitaxial layer 112 covered by the implantation mask 210 define the second regions 12 of the superjunction region 1. Thus, a distance between neighboring openings 211 of the first implantation mask 210 defines a width of the second regions 12 in the finished superjunction region 1.

Referring to FIG. 15B, after the first implantation process illustrated in FIG. 15A, the method further includes forming a second implantation mask 220 on top of the epitaxial layer 112. The second implantation mask 220 covers those regions of the epitaxial layer 112 that were covered by the first implantation mask 210 in the first implantation process and additionally covers sections of the implanted regions 13′ adjoining the second regions 12. The method further includes a second implantation process, which includes implanting first type dopant atoms via the openings 221 of the second implantation mask 220 into the epitaxial layer 112 to form second implanted regions 11′.

Each of the first and second implantation processes may include two or more implantation processes at different implantation energies.

Referring to FIG. 15C, the method further includes an annealing process in which the first type dopant atoms implanted in the first implantation process and the second implantation process are activated.

In the method illustrated in FIGS. 15A-15C, those portions of the epitaxial layer 112 that are not covered by the first implantation mask 210 but covered by the second implantation mask 220, after the annealing process, form the third regions 13. A doping concentration of the third regions 13 is defined by the implantation dose in the first implantation process and the basic doping of the epitaxial layer 112. As explained above, the basic doping of the epitaxial layer 112 may result from in-situ doping the epitaxial layer 112 during the epitaxial growth process or from a blanket implantation process. Those regions of the epitaxial layer 112 that are not covered by the first implantation mask 210 and not covered by the second implantation mask 220, after the annealing process, form the first regions 11. A doping concentration of the first regions 11 is defined by the implantation dose in the first implantation process and the implantation dose in the second implantation process and the basic doping of the epitaxial layer 112.

According to one example, the second implantation mask 220 is formed based on the first implantation mask 210 by a spacer process in which implantation mask material is formed along sidewalls of the openings 211 in the first implantation mask 210. In this way, the third regions 13 can be generated in a self-aligned manner between the first and second regions 11, 12.

Some of the aspects of the superjunction device and the method for producing the superjunction device are briefly summarized in the following.

According to one example, the superjunction device includes a semiconductor body including an inner region and an edge region laterally surrounding the inner region; a superjunction region including first regions of an effective first doping type and second regions of an effective second doping type arranged alternatingly in a first lateral direction of the semiconductor body. The first regions, in the inner region, have a first width and are spaced apart from each other at a first distance, in the first edge region section, have a second width and are spaced apart from each other at a second distance, and, in the inner region and the edge region, are elongated in a second lateral direction different from the first lateral direction. The second width is smaller than the first width and the second distance is smaller than the first distance.

According to one example, the first width is selected from a range of between 1.2 times and 3 times the second width.

According to one example, each of the first regions arranged in the inner region, in the second lateral direction, merges into two first regions arranged in the edge region. According to one example, the first width is at least approximately twice the second width.

According to one example, the distance between two neighboring first regions equals a width of a respective second region arranged between the two neighboring first regions.

According to one example, the superjunction region further includes third regions having a lower effective doping concentration than the first regions and the second regions, wherein each third region is arranged between a respective first region and a neighboring second region. According to one example, the third regions are intrinsic, or have a doping concentration that is lower than 10% of a doping concentration of each of the first and second regions.

According to one example, each of the first regions includes dopant atoms of the second doping type, and a doping concentration of the dopant atoms of the second doping type in the first regions at least approximately equals a doping concentration of dopant atoms of the second doping type in the second regions.

According to one example, the superjunction device is a transistor device and includes a plurality of transistor cells arranged in the inner region of the semiconductor body. Each of the transistor cells may include a body region of the first doping type; a source region of the second doping type; and a gate electrode dielectrically insulated from the body region by a gate dielectric. The body region of each transistor cell may adjoins at least one of the first regions and may adjoin at least one of the second regions. The transistor device may further include a drain region electrically coupled to the second regions.

According to one example, the edge region includes a first edge region section and a second edge region section, wherein the second edge region section laterally surrounds the first edge region section and the superjunction region. A doping concentration of the fourth region may at least approximately equal the doping concentration of the second regions.

Another example relates to a method for forming a superjunction region of a superjunction device. The superjunction device includes a semiconductor body including an inner region and an edge region laterally surrounding the inner region; a superjunction region including first regions of an effective first doping type and second regions of an effective second doping type arranged alternatingly in a first lateral direction of the semiconductor body, wherein the first regions, in the inner region, have a first width and are spaced apart from each other at a first distance, in the first edge region section, have a second width and are spaced apart from each other at a second distance, in the inner region and the edge region, are elongated in a second lateral direction different from the first lateral direction, and wherein the second width is smaller than the first width and the second distance is smaller than the first distance. Forming the superjunction region includes implanting dopant atoms of the first doping type into a semiconductor layer having a doping concentration of the second doping type, and an annealing process.

According to one example, the first width is selected from a range of between 1.2 times and 3 times the second width.

According to one example, each of the first regions arranged in the inner region, in the second lateral direction, merges into two first regions arranged in the edge region.

According to one example, implanting the dopant atoms of the first doping type includes a first implantation process in which dopant atoms of the first doping type are implanted into the semiconductor layer using a first implantation mask, and a second implantation process in which dopant atoms of the first doping type are implanted into the semiconductor layer using a second implantation mask. The second implantation mask is aligned with regard to the first implantation mask such that the second regions are covered by both the first implantation mask and the second implantation mask, regions that are not covered by both the first implantation mask and the second implantation mask, after the annealing process, form the first regions, and regions that are not covered by the first implantation mask and covered by the second implantation mask, after the annealing process, form third regions having a lower effective doping concentration than the first regions and the second regions.

1. A superjunction device, comprising:
a semiconductor body comprising an inner region and an edge region laterally surrounding the inner region; and
a superjunction region comprising first regions of an effective first doping type and second regions of an effective second doping type arranged alternatingly in a first lateral direction of the semiconductor body,
wherein in the inner region, the first regions have a first width and are spaced apart from each other at a first distance,
wherein in the edge region, the first regions have a second width and are spaced apart from each other at a second distance,
wherein in the inner region and the edge region, the first regions are elongated in a second lateral direction different from the first lateral direction, and
wherein the second width is smaller than the first width and the second distance is smaller than the first distance.

2. The superjunction device of claim 1,
wherein the first width is between 1.2 times and 3 times the second width.

3. The superjunction device of claim 1,
wherein each of the first regions arranged in the inner region, in the second lateral direction, merges into two first regions arranged in the edge region.

4. The superjunction device of claim 3,
wherein the first width is at least approximately twice the second width.

5. The superjunction device of claim 1,
wherein the distance between two neighboring first regions equals a width of a respective second region arranged between the two neighboring first regions.

6. The superjunction device of claim 1, wherein the superjunction region further comprises:
third regions having a lower effective doping concentration than the first regions and the second regions; and
wherein each third region is arranged between a respective first region and a neighboring second region.

7. The superjunction device of claim 6, at least one of:
wherein the third regions are intrinsic; or
wherein a doping concentration of the third regions is lower than 10% of a doping concentration of each of the first regions and the second regions.

8. The superjunction device of claim 1,
wherein each of the first regions comprises dopant atoms of the second doping type; and
wherein a doping concentration of the dopant atoms of the second doping type in the first regions at least approximately equals a doping concentration of dopant atoms of the second doping type in the second regions.

9. The superjunction device of claim 1,
wherein the superjunction device is a transistor device and includes a plurality of transistor cells arranged in the inner region of the semiconductor body.

10. The superjunction device of claim 7, wherein each transistor cell comprises:
a body region of the first doping type;
a source region of the second doping type; and
a gate electrode dielectrically insulated from the body region by a gate dielectric.

11. The superjunction device of claim 10,
wherein the body region of each transistor cell adjoins at least one of the first regions and adjoins at least one of the second regions.

12. The superjunction device of claim 9 further comprising:
a drain region electrically coupled to the second regions.

13. The superjunction device of claim 1,
wherein the edge region comprises a first edge region section and a second edge region section; and
wherein the second edge region section laterally surrounds the first edge region section and the superjunction region.

14. The superjunction device of claim 13,
wherein a doping concentration of a fourth region at least approximately equals the doping concentration of the second regions.

15. A method, comprising:
forming a superjunction region of a superjunction device, wherein the superjunction device comprises:
a semiconductor body comprising an inner region and an edge region laterally surrounding the inner region;
a superjunction region comprising first regions of an effective first doping type and second regions of an effective second doping type arranged alternatingly in a first lateral direction of the semiconductor body,
wherein in the inner region, the first regions have a first width and are spaced apart from each other at a first distance,
wherein in the edge region, the first regions have a second width and are spaced apart from each other at a second distance,
wherein in the inner region and the edge region, the first regions are elongated in a second lateral direction different from the first lateral direction, and
wherein the second width is smaller than the first width and the second distance is smaller than the first distance,
wherein forming the superjunction region comprises:
implanting dopant atoms of the first doping type into a semiconductor layer having a doping concentration of the second doping type; and
performing an annealing process.

16. The method of claim 15,
wherein the first width is between 1.2 times and 3 times the second width.

17. The method of claim 15,
wherein each of the first regions arranged in the inner region, in the second lateral direction, merges into two first regions arranged in the edge region.

18. The method of claim 15,
wherein implanting the dopant atoms of the first doping type comprises:
a first implantation process in which dopant atoms of the first doping type are implanted into the semiconductor layer using a first implantation mask; and
a second implantation process in which dopant atoms of the first doping type are implanted into the semiconductor layer using a second implantation mask,
wherein the second implantation mask is aligned with regard to the first implantation mask such that
the second regions are covered by both the first implantation mask and the second implantation mask,
regions that are not covered by both the first implantation mask and the second implantation mask, after the annealing process, form the first regions, and
regions that are not covered by the first implantation mask and covered by the second implantation mask, after the annealing process, form third regions having a lower effective doping concentration than the first regions and the second regions.

19. A superjunction device, comprising:
a semiconductor body comprising an inner region and an edge region laterally surrounding the inner region; and
a superjunction region comprising first regions of an effective first doping type and second regions of an effective second doping type arranged alternatingly in a first lateral direction of the semiconductor body,
wherein in the inner region, the first regions have a first width and are spaced apart from each other at a first distance,
wherein in the edge region, the first regions have a second width and are spaced apart from each other at a second distance, and
wherein in the inner region and the edge region, the first regions are elongated in a second lateral direction different from the first lateral direction.

20. The superjunction device of claim 19,
wherein each of the first regions arranged in the inner region, in the second lateral direction, merges into two first regions arranged in the edge region.
